(19) United States
(12) Patent Application Publication
(10) Pub. No.: US 2024/0347541 A1
(43) Pub. Date: Oct. 17, 2024

(54) DRIVING BACKPLANE AND PREPARATION METHOD THEREFOR, AND DISPLAY DEVICE AND PREPARATION METHOD THEREFOR

(71) Applicant: BOE Technology Group Co., Ltd., Beijing (CN)

(72) Inventors: Jianhua DU, Beijing (CN); Jinxiang XUE, Beijing (CN); Xinhong LU, Beijing (CN); Yingwei LIU, Beijing (CN); Meng ZHAO, Beijing (CN); Hao WU, Beijing (CN); Feng GUAN, Beijing (CN); Yang LV, Beijing (CN); Chaolu WANG, Beijing (CN)

(73) Assignee: BOE Technology Group Co., Ltd., Beijing (CN)

(21) Appl. No.: 18/749,666

(22) Filed: Jun. 21, 2024

Related U.S. Application Data
(63) Continuation of application No. PCT/CN2021/140565, filed on Dec. 22, 2021.

(51) Int. Cl. H01L 27/12; H01L 25/075; H01L 25/16; H01L 33/62

(52) U.S. Cl. CPC H01L 27/1218; H01L 25/0753; H01L 25/167; H01L 27/1244; H01L 27/1262; H01L 33/62

(57) ABSTRACT

A driving backplane, a display device and preparation methods therefor are provided. The method includes: providing a base substrate with first, second surfaces and a side surface connected therebetween; forming a flexible film layer on the first surface, and patterning the flexible film layer to form a first opening portion including first, second and third parts sequentially connected; bending partial flexible film layer to the second surface, such that first, second and third parts are opposite to the first, side and second surfaces; forming a conductive layer on a side of the flexible film layer away from the base substrate by using the flexible film layer as a mask, the conductive layer being formed in at least a part of the first opening portion to form a conductive strip; and at least removing the flexible film layer and the conductive layer around the conductive strip.

### CROSS-REFERENCE TO RELATED APPLICATION

The present disclosure is a U.S. Continuation Application of International Application No. PCT/CN2021/140565, filed on Dec. 22, 2021, entitled “DRIVING BACKPLANE AND MANUFACTURING METHOD THEREFOR, AND DISPLAY DEVICE AND MANUFACTURING METHOD THEREFOR”, the entire content of which is incorporated herein by reference.

### TECHNICAL FIELD

The present disclosure relates to a field of display technology, and more particularly to a driving backplane and a method for preparing the driving backplane, a display device including the driving backplane and a method for preparing the display device.

### BACKGROUND

MLED (Micro Light-emitting Diode or Mini Light-Emitting Diode) display devices have significant advantages in terms of the brightness, resolution, contrast, energy consumption, service life, response speed, and thermal stability, etc., resulting in an increasingly wide range of applications.

However, it is difficult to meet customer requirements with a side lead process of the current MLED.

It should be noted that the information disclosed in the Background section above is only for enhancing the understanding of the background of the present disclosure and thus, may include information that does not constitute prior art known to those of ordinary skill in the art.

### SUMMARY

The purpose of the present disclosure is to overcome the shortcomings of the prior art and provide a method for preparing a driving backplane and a driving backplane, a display device including the driving backplane and a method for preparing the display device.

According to an aspect of the present disclosure, a method for preparing a driving backplane is provided and includes:
providing a base substrate, where the base substrate is provided with a first surface and a second surface opposite to each other, a side surface is connected between the first surface and the second surface;
forming a flexible film layer on the first surface, and patterning the flexible film layer to form a first opening portion, where the first opening portion includes a first part, a second part and a third part sequentially connected with each other;
bending a part of the flexible film layer to the second surface, such that the first part is opposite to the first surface, the second part is opposite to the side surface, and the third part is opposite to the second surface;
forming a conductive layer on a side of the flexible film layer away from the base substrate by using the flexible film layer as a mask, where the conductive layer is formed in at least a part of the first opening portion to form a conductive strip; and
at least removing the flexible film layer and the conductive layer that are disposed around the conductive strip.

In an exemplary embodiment, before patterning the flexible film layer, the method further includes:
forming an isolation layer on the side of the flexible film layer away from the base substrate; and
patterning the isolation layer while patterning the flexible film layer, such that the isolation layer forms a second opening portion, where a rate for patterning the isolation layer is less than a rate for patterning the flexible film layer, such that the isolation layer forms a protrusion portion protruding from the flexible film layer at the second opening portion.

In an exemplary embodiment, a material of the isolation layer is an inorganic material, and a material of the flexible film layer is an organic material.

In an exemplary embodiment, after patterning the flexible film layer, the method further includes:
removing a part of the base substrate such that orthographic projections of the second part and the third part on a first plane does not overlap with an orthographic projection of the base substrate on the first plane, where the first plane is parallel to the base substrate.

In an exemplary embodiment, before removing the part of the base substrate, the method further includes:
bending the flexible film layer towards a side away from the second surface, such that a part of the flexible film layer is separated from the base substrate.

In an exemplary embodiment, after removing the part of the base substrate, the method further includes:
forming chamfers by processing an edge connected between the side surface and the first surface and an edge connected between the side surface and the second surface.

In an exemplary embodiment, at least removing the flexible film layer and the conductive layer that are disposed around the conductive strip includes:
peeling off the flexible film layer from the second surface, an end surface, and at least a part of the first surface; and
at least cutting off the flexible film layer and the conductive layer that are disposed around the conductive strip.

In an exemplary embodiment, after bending the part of the flexible film layer to the second surface, the method further includes:
applying a set tensile force to an end portion of the flexible film layer bent to the second surface, such that the flexible film layer is fitted with the base substrate.

In an exemplary embodiment, after patterning the flexible film layer to form the first opening portion, the method further includes:
forming a plurality of switch units provided in an array and a plurality of connection wires on a side of the base substrate, where the connection wire is connected between the switch unit and the conductive strip;
forming a metal layer on a side of the switch unit away from the base substrate, where the metal layer is connected to the switch unit;
forming a protective material layer on a side of the metal layer away from the base substrate;
sequentially patterning the protective material layer and the metal layer, where the protective material layer forms a protective layer and the metal layer forms a connection pin; and
forming an insulation layer group on a side of the protective layer away from the base substrate, and patterning the insulation layer group to form a via hole, where the via hole is communicated with the protective layer.

In an exemplary embodiment, a material of the protective material layer is an oxide.

In an exemplary embodiment, a set etching amount of the protective material layer is greater than a set etching amount of the metal layer, such that after sequentially patterning the protective material layer and the metal layer, an orthographic projection of the protective layer on the base substrate is located within an orthographic projection of a surface of the connection pin away from the base substrate on the base substrate.

In an exemplary embodiment, before forming the metal layer on the side of the switch unit away from the base substrate, the method further includes:
forming a first conductive layer on a side of the switch unit away from the base substrate, where the metal layer is formed on a side of the first conductive layer away from the base substrate; and
patterning the first conductive layer, while patterning the metal layer, to form a conductive pin.

According to another aspect of the present disclosure, a driving backplane is provided; the driving backplane is prepared by any one of the above methods.

In an exemplary embodiment, the driving backplane includes:
a base substrate, provided with a first surface and a second surface opposite to each other, where a side surface is connected between the first surface and the second surface;
a flexible film layer, provided on the first surface;
a buffer layer, located on a side of the flexible film layer away from the base substrate; and
a conductive strip, provided on at least one end portion of the base substrate, where the conductive strip includes a first conductive part, a second conductive part, and a third conductive part sequentially connected, the first conductive part is provided on the first surface, the second conductive part is provided on the side surface, and the third conductive part is provided on the second surface.

In an exemplary embodiment, the driving backplane further includes:
an isolation layer, provided between the flexible film layer and the buffer layer.

In an exemplary embodiment, the driving backplane further includes:
a plurality of switch units provided in an array and a plurality of connection wires, where the plurality of switch units and the plurality of connection wires are provided on a side of the buffer layer away from the base substrate, and the connection wire is connected between the switch unit and the conductive strip;
a connection pin, provided on a side of the switch unit away from the base substrate, where the connection pin is connected to the switch unit;
a protective layer, provided on a side of the connection pin away from the base substrate; and
an insulation layer group, provided on a side of the protective layer away from the base substrate, where the insulation layer group is defined with a via hole, and the via hole is communicated to the protective layer.

According to another aspect of the present disclosure, a method for preparing a display device is provided and includes
preparing and forming the driving backplane by any one of the above methods for preparing the driving backplane;
removing at least a part of the protective layer to expose at least a part of the connection pin; and
mounting a light-emitting device on a side of the driving backplane, where the light-emitting device is connected to the connection pin.

According to another aspect of the present disclosure, a display device prepared by the above method for preparing the display device.

In an exemplary embodiment, the light-emitting device is a micro light-emitting diode.

It should be understood that the preceding general description and the following detailed description are exemplary and explanatory only and are not restrictive of the present disclosure.

### BRIEF DESCRIPTION OF THE DRAWINGS

The accompanying drawings here are incorporated in the specification and constitute a part of this specification, show embodiments in accordance with the present disclosure and serve to explain the principles of the present disclosure together with the specification. Obviously, the drawings in the following description are turned only some embodiments of the present disclosure, and for those ordinary skills in the art, other drawings may also be obtained from these drawings without creative efforts.

FIG. 1 is a flowchart illustrating an exemplary embodiment of a method for preparing a driving backplane of the present disclosure.

FIG. 2 is a structural schematic diagram after patterning a flexible film layer in a method for preparing a driving backplane of the present disclosure.

FIG. 3 is a partial cross-sectional structural schematic diagram after patterning a flexible film layer and an isolation layer in a method for preparing a driving backplane of the present disclosure.

FIGS. 4-9 are structural diagrams of various steps of forming a switch unit in a display area in a method for preparing a driving backplane of the present disclosure.

FIGS. 10-16 are structural diagrams of various steps of a side lead process in a method for preparing a driving backplane of the present disclosure.

FIG. 17 is a structural schematic diagram of an exemplary embodiment of a driving backplane of the present disclosure.

FIG. 18 is a flowchart illustrating an exemplary embodiment of a method for preparing a display device of the present disclosure.

FIG. 19 is a structural schematic diagram of a driving backplane with a protective layer removed of the present disclosure.

FIG. 20 is a structural schematic diagram of an exemplary embodiment of a display device of the present disclosure.

### REFERENCE NUMERALS

1. base substrate; 101. first surface; 102. second surface; 103. side surface; 1a. substrate motherboard;
2. light-shielding layer; 3. buffer layer;
4. active layer; 41. conductor portion; 42. channel portion;
5. gate insulation layer; 6. gate; 61. connection line;
7. interlayer dielectric layer; 71. first via hole; 72. second via hole;
81. source 82. drain; 83. ground wire;
9. first planarization layer; 91. third via hole; 92. fourth via hole;
10. first insulation layer; 1001. fifth via hole; 1002. sixth via hole;
11. first conductive layer; 111. conductive pin;
12. metal layer; 121. connection pin;
13. protective material layer; 131. protective layer;
14. second insulation layer; 15. second planarization layer; 151. seventh via hole; 152. eighth via hole;
16. flexible film layer; 161. first opening portion; 1611. first part; 1612. second part; 1613. third part;
17. conductive layer; 171. conductive strip; 1711. first conductive part; 1712. second conductive part; 1713. third conductive part;
18. photoresist; 19. connection portion;
20. isolation layer; 201. protrusion portion; 202. second opening portion;
21. shielding plate; 22. light-emitting device; 23. circuit board; AA, display area; FA, non-display area.

### DETAILED DESCRIPTION

Example embodiments will now be described more fully with reference to the accompanying drawings. However, the example embodiments may be implemented in various forms, and should not be construed as being limited to the examples set forth herein; on the contrary, these embodiments are provided to make the present disclosure more comprehensive and complete, and fully convey the concept of the example embodiments to those skilled in the art. The same reference numerals in the figures indicate the same or similar structures, and thus their detailed descriptions will be omitted. In addition, the drawings are only schematic illustrations of the present disclosure, and are not necessarily drawn to scale.

Although relative terms such as “upper” and “lower” are used in this specification to describe the relative relationship between labeled one component and another component, these terms are used in this specification only for convenience, for example, exemplary directions as shown according to the drawings. It may be understood that if the labeled device is turned over and turned upside down, the component described as “upper” will become the “lower” component. When a structure is “on” another structure, it may mean that a certain structure is integrally formed on other structures, or that a certain structure is “directly” provided on other structures, or that a certain structure is “indirectly” provided on other structures through another structure.

The terms “a”, “an”, “the”, and “said” are used to indicate the presence of one or more elements/components/etc.; the terms “include” and “comprise” are used to mean open-ended inclusion and means that there may be additional elements/components/etc. in addition to the listed elements/components/etc.; the terms “first”, “second”, and “third” are only used as marks, not limit the number of its objects.

In the related art, 3D sputtering may be performed on an end portion of the base substrate where a side lead needs to be formed, so as to form a conductive layer, and then a side conductive strip may be formed by laser etching. However, since a width of the laser is a relatively large, an etching precision is insufficient, which is not suitable for a product with high precision requirement. Moreover, solid particles formed after laser ablation of the conductive layer are not easy to remove, and the solid particles may fall into a display area AA to affect the display, or the solid particles may adhere to the conductive strip to affect the conductivity effect; In addition, a disposable mask plate may also be used as a mask, and the 3D sputtering may be performed to form the conductive strip, but the mask needs to be aligned, which increases the alignment process, thereby increasing the cost and reducing the efficiency.

In addition, a bottleneck process of the MLED technology lies in reducing a splicing gap, which is also limited by technology such as the side lead process. Improvement of the side lead process is very favorable to reduce a size of the splicing.

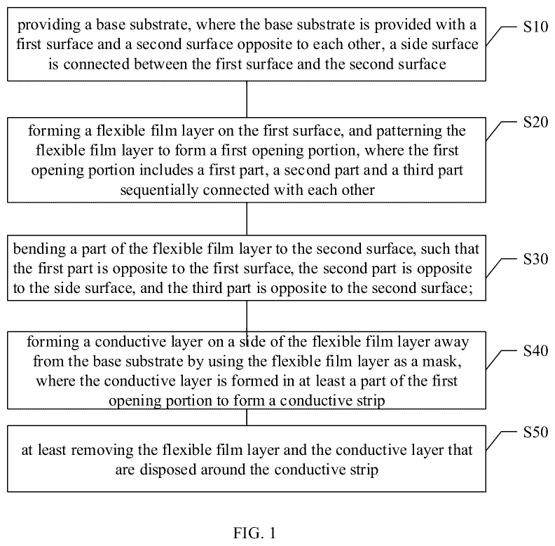

The present disclosure provides a method for preparing a driving backplane, as shown in FIG. 1. The preparation method may include the following steps:
step S10: providing a base substrate 1, where the base substrate 1 is provided with a first surface 101 and a second surface 102 opposite to each other, a side surface 103 is connected between the first surface 101 and the second surface 102;
step S20, forming a flexible film layer 16 on the first surface 101, and patterning the flexible film layer 16 to form a first opening portion 161, where the first opening portion 161 includes a first part 1611, a second part 1612 and a third part 1613 sequentially connected with each other;
step S30, bending a part of the flexible film layer 16 to the second surface 102, such that the first part 1611 is opposite to the first surface 101, the second part 1612 is opposite to the side surface 103, and the third part 1613 is opposite to the second surface 102;
step S40, forming a conductive layer 17 on a side of the flexible film layer 16 away from the base substrate 1 by using the flexible film layer 16 as a mask, where the conductive layer 17 is formed in at least a part of the first opening portion 161 to form a conductive strip 171;
step S50, at least removing the flexible film layer 16 and the conductive layer 17 that are disposed around the conductive strip 171.

In the driving backplane and the method for preparing the same disclosed herein, the conductive strip 171 of the side edge is directly formed on at least one end of the base substrate 1 by using the flexible film layer formed on the side of the base substrate as the mask without the alignment process, so as to simplify the process, and thereby reduce the cost and improve the efficiency. Moreover, the precision for the patterning is relatively high, and thus the conductive strip 171 formed has a relatively high precision, which may meet requirements of the high-precision product. In addition, the patterning does not produce etching foreign matter, and thus, the display effect and the conductive effect cannot be affected due to the etching foreign matter.

Each step of the method for preparing the driving backplane will be described in detail below.

In step S10: a base substrate 1 is provided, where the base substrate 1 is provided with a first surface 101 and a second surface 102 opposite to each other, a side surface 103 is connected between the first surface 101 and the second surface 102.

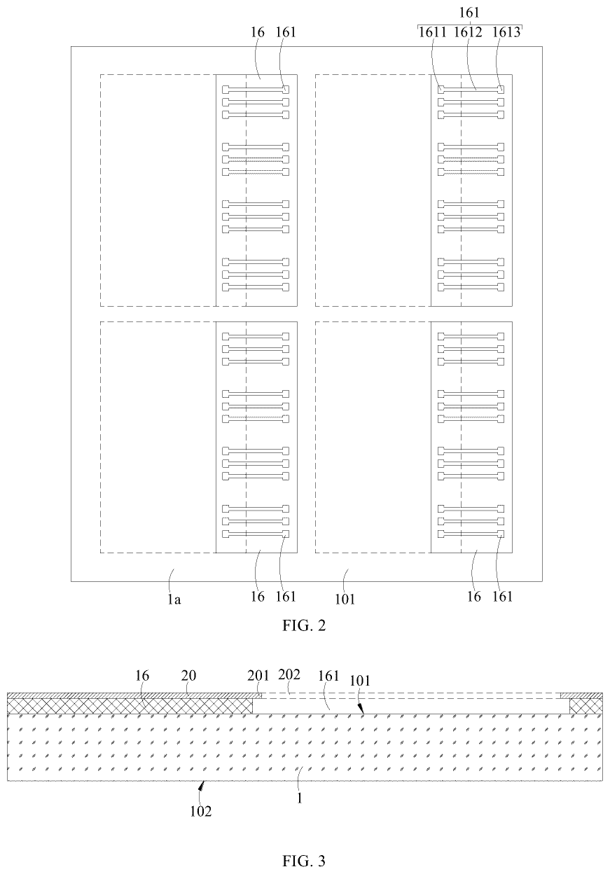

In the exemplary embodiment, as shown in FIG. 2, the substrate motherboard 1a is set to be relatively large, and multiple other structures of the driving backplane may be formed on a single substrate motherboard 1a. A dashed line in the drawing represents a region of the substrate motherboard 1a occupied by one driving backplane, and a plurality of base substrates 1 are formed after cutting the substrate motherboard 1a.

The base substrate 1 may be set as a rectangular plate, the base substrate 1 is provided with a first surface 101 and a second surface 102 opposite to each other, and both the first surface 101 and the second surface 102 are rectangular. Four side surfaces 103 are connected between the first surface 101 and the second surface 102, and the four side surfaces 103 are all rectangular. Of course, in another exemplary embodiment of the present disclosure, the base substrate 1 may be set as a circular plate or an elliptical plate. In this case, the first surface 101 and the second surface 102 are both circular or elliptical, and there is one side surface 103 connected between the first surface 101 and the second surface 102. The base substrate 1 may also be of other shapes, which are not described here.

The base substrate 1 may include a display area AA and a non-display area FA, and the display area AA is connected to the non-display area FA. It should be noted that the division of display area AA and the non-display area FA in the drawings is only illustrative, which is for ease of understanding and does not constitute a limitation of the present disclosure.

A material of base substrate 1 may include an inorganic material, such as glass, quartz, or metal. The material of base substrate 1 may also include an organic material, for example, the organic material may be a resin material such as polyimide, polycarbonate, polyacrylate, polyetherimide, polyethersulfone, polyethylene terephthalate, and polyethylene naphthalate, etc. The base substrate 1 may be formed by a plurality of material layers, for example, the base substrate 1 may include a plurality of substrate layers, and a material of the substrate layer may be any of the aforementioned materials. Of course, the base substrate 1 may also be set as a single layer, which may be made of any of the aforementioned materials.

in step S20, a flexible film layer 16 is formed on the first surface 101, and the flexible film layer 16 is patterned to form a first opening portion 161, the first opening portion 161 includes a first part 1611, a second part 1612 and a third part 1613 sequentially connected with each other.

In the present exemplary embodiment, as shown in FIG. 2, the flexible film layer 16 is formed on the first surface 101 of the base substrate 1 through a coating process. A material of the flexible film layer 16 may be organic, including but not limited to PI (polyimide), and a thickness of the flexible film layer 16 may be greater than or equal to 5 microns and less than or equal to 20 microns.

As shown in FIG. 3, an isolation layer 20 is formed on a side of the flexible film layer 16 away from the base substrate 1 through processes such as deposition and sputtering. A rate for patterning the isolation layer 20 is less than a rate for patterning the flexible film layer 16. The rate for patterning processing may be an etching rate, that is, an etching rate for the isolation layer 20 is less than an etching rate for the flexible film layer 16.

A thickness of the isolation layer 20 may be greater than or equal to 0.5 microns and less than or equal to 2 microns. A material of isolation layer 20 may be inorganic, including but not limited to metal, such as Al, Mo, etc. The material of isolation layer 20 may also be silicon oxide, silicon nitride, silicon nitride, etc. Of course, the isolation layer 20 may also be made of other materials, as long as the rate for patterning the isolation layer 20 is less than the rate for patterning the flexible film layer 16. The inorganic isolation layer 20 is not prone to break during multiple bending processes in subsequent process.

It should be noted that in some other exemplary embodiments of the present disclosure, an isolation layer 20 may not be formed on a side of the flexible film layer 16 away from the base substrate 1. That is, after the flexible film layer 16 is formed, the flexible film layer 16 is directly patterned.

The flexible film layer 16 and the isolation layer 20 may cover the entire substrate motherboard 1a, and an unnecessary part is then removed during subsequent patterning process. As shown in FIG. 3, the flexible film layer 16 and the isolation layer 20 are patterned to correspondingly form a first opening portion 161 and a second opening portion 202. Specifically, a photoresist 18 layer is formed on a side of the isolation layer 20 away from the base substrate 1, a mask plate is placed on a side of the photoresist 18 layer away from the base substrate 1, and the photoresist layer 18 is illuminated and developed to remove the illuminated photoresist 18; finally, the flexible film layer 16 and the isolation layer 20 are etched using the photoresist 18 layer as a mask.

The isolation layer 20 may be pre-etched to form a relatively small second opening portion on the isolation layer 20; then, a gas different from that of the above etching is used to etch the flexible film layer 16, and the gas etching the flexible film layer 16 has a very low rate for etching the isolation layer 20, as shown in FIG. 3. Since a rate for etching the isolation layer 20 is less than a rate for etching the flexible film layer 16, after the same etching time, an etching amount of the flexible film layer 16 is greater than an etching amount of the isolation layer 20, such that the isolation layer 20 forms a protrusion portion 201 protruding from the flexible film layer 16 at the second opening portion 202, that is, the second opening portion 202 is less than the first opening portion 161, and edges of the second opening portion 202 is located within edges of the first opening portion 161.

As shown in FIG. 2, the first opening portion 161 may be a plurality of via holes, and the via hole may be a long strip shape; the via hole may include the first part 1611, the second part 1612, and the third part 1613; the second part 1612 is connected between the first part 1611 and the third part 1613, end portions of the first part 1611 and the third part 1613 away from the second part 1612 may be set as square via holes, and the second part 1612 may be set as a rectangular via hole.

In addition, in some other exemplary embodiments of the present disclosure, the first opening portion 161 may also be a notch (i.e. an unclosed opening), and the notch may be a long strip shape; the specific shape of the notch may be the same as the above via hole, except that a side of the third part 1613 away from the second part 1612 is set to be open, such that the entire first opening portion 161 is formed as an opening portion with a notch; furthermore, end portions of the first part 1611 and the third part 1613 away from the second part 1612 may be set as circular via holes or elliptical via holes.

While the flexible film layer 16 and the isolation layer 20 are patterned to form the first opening portion 161 and the second opening portion 202, the flexible film layer 16 and the isolation layer 20 on other regions may be removed. For example, a part of the flexible film layer 16 and the isolation layer 20 on the display area AA may be removed, and that is, a part of the flexible film layer 16 and the isolation layer 20 that are located in the display area AA may be retained. The retention of the part of the flexible film layer 16 and the isolation layer 20 may prevent the flexible film layer 16 and the isolation layer 20 from being pulled off during the side lead process.

In the present exemplary embodiment, referring to FIG. 4, after the flexible film layer 16 and the isolation layer 20 are patterned, a light-shielding layer 2 may be formed on a first surface of the base substrate; then, a buffer layer 3 may be formed on a side of the isolation layer 20 located in the display area AA away from the base substrate 1 and a side of the light-shielding layer 2 away from the base substrate 1, and the isolation layer 20 may be covered by the buffer layer 3. Of course, in the case where the flexible film layer 16 and the isolation layer 20 are not formed on the display area AA, the buffer layer 3 may be formed on a side of the light-shielding layer 2 away from the base substrate 1; in the case where the isolation layer 20 is not formed, the buffer layer 3 may be formed on a side of the flexible film layer 16 away from the base substrate 1 and a side of the light-shielding layer 2 away from the base substrate 1.

A plurality of switch units provided in an array and a plurality of connection wires are formed on a side of buffer layer 3 away from base substrate 1. The switch unit may include a capacitor and at least two thin film transistors, the thin film transistor may include an active layer 4, a gate 6, a source 81, and a drain; Specifically, the active layer 4 is formed on a side of the buffer layer 3 away from the base substrate 1. The active layer 4 may include a channel portion 42 and a conductor portion 41 provided at both ends of the channel portion 42, a gate insulation layer 5 is formed on a side of the active layer 4 away from the base substrate 1, a gate 6 is formed on a side of the gate insulation layer 5, a connection line 61 is formed on a side of the buffer layer 3 away from the base substrate 1 while the gate 6 is formed, an interlayer dielectric layer 7 is formed on a side of the gate 6 away from the base substrate 1, and a first via hole 71 and a second via hole 72 are defined on the interlayer dielectric layer 7. The first via hole 71 is communicated to the conductor portion 41, and the second via hole 72 is communicated to the connection line 61; a ground wire 83, a source 81, and a drain 82 are formed on a side of the interlayer dielectric layer 7 away from the base substrate 1; the source 81 and the drain 82 are respectively connected to two conductor portions 41 through two first via holes 71, and the ground wire 83 is connected to the connection line 61 through the second via hole 72.

It should be noted that in the case where a thin film transistor with opposite polarity is used, or a current direction during the circuit operation is changed, the functions of “source 81” and “drain 82” are sometimes interchanged with each other. Therefore, in this specification, the “source 81” and the “drain 82” may be interchanged with each other.

The connection wires may include gate wires, data wires, power wires, etc.; the connection wire is connected between the switch unit and the conductive strip 171, and an electrical signal is transmitted through the conductive strip 171 and the connection wire. The gate wire may be formed while forming the gate 6, while the data wire and power wire may be formed while forming the source 81 and drain 82.

In addition, while the connection wire is formed, a connection portion 19 connected between the conductive strip 171 and the connection wire is formed. The connection portion 19 is formed at an end of the first portion 1611 of the first opening portion 161 close to the display area AA and at an end of the second opening portion 202 close to the display area AA.

A first planarization layer 9 is formed on a side of the switch unit away from the base substrate 1, and a third via hole 91 and a fourth via hole 92 are defined on the first planarization layer 9; a first insulation layer 10 is formed on a side of the first planarization layer 9 away from the base substrate 1, and a fifth via hole and a sixth via hole 1002 are defined on the first insulation layer 10.

A first conductive layer 11 is formed on a side of the insulation layer away from the base substrate 1, the first conductive layer 11 is connected to the source and the drain through two third via holes 91, and the first conductive layer 11 is connected to the ground wire 83 through the fourth via hole 92. The first conductive layer 11 may be a nickel molybdenum alloy. The first conductive layer 11 may prevent the subsequently formed metal layer 12 from seeping into a film layer below the metal layer 12.

A metal layer 12 is formed by depositing on a side of the first conductive layer 11 away from the base substrate 1, a material of the metal layer 12 may be copper or other metal materials; the metal layer 12 is prone to natural oxidation during the high-temperature annealing process, and the conductivity of the naturally oxidized metal layer 12 is relatively poor, and in the subsequent leaching gold technology process, the adhesion to gold is poor, which affects the performance of the driving backplane. However, if the high-temperature annealing process is not performed, it may lead to abnormalities in the thin film transistor, such as the occurrence of a discrete transfer curve, a positive or negative bias of Vth, etc.

A protective material layer 13 is formed by depositing on a side of the metal layer 12 away from the base substrate 1, a material of the protective material layer 13 may be oxide, such as IGZO (Indium Gallium Zinc Oxide), ITZO (Indium Tin Zinc Oxide), etc; IGZO and ITZO may react quickly with dilute acid. Of course, the protective material layer 13 may also be other oxides. A thickness of the protective material layer 13 is greater than or equal to 10 nm and less than or equal to 50 nm. When the protective material layer 13 is deposited and formed, the reactive sputtering is not required to introduce O₂, and the metal layer 12 will not be oxidized.

During the high-temperature annealing process, the protective material layer 13 may protect the metal layer 12 from the natural oxidation, such that the high-temperature annealing process may be performed on the driving backplane, which avoids abnormalities, such as the occurrence of a discrete transfer curve, a positive or negative bias of Vth, etc., in the thin film transistor.

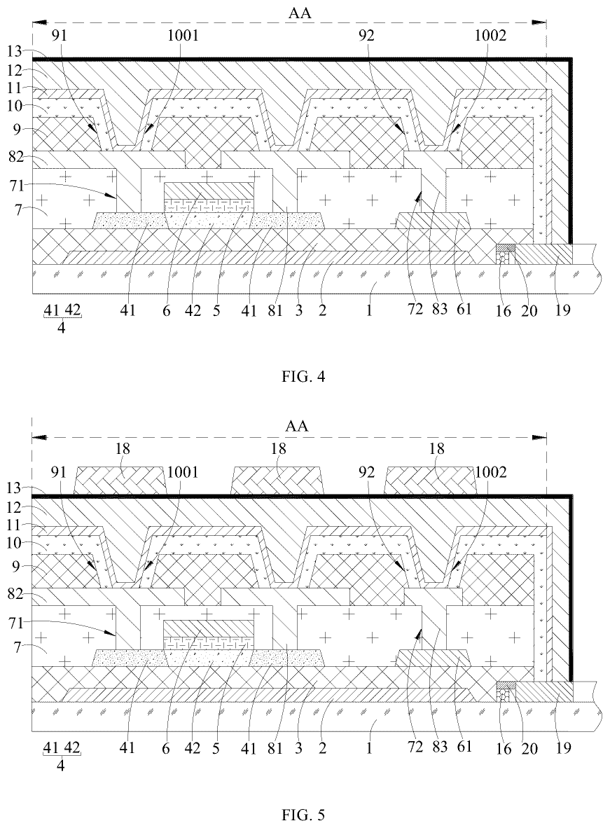

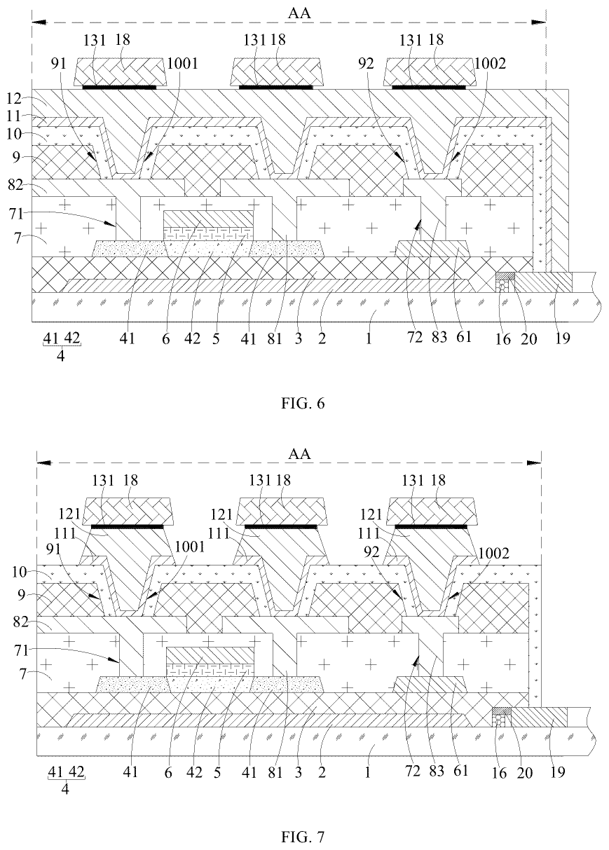

As shown in FIGS. 5-7, a photoresist 18 is formed on a side of the metal layer 12 away from the base substrate 1. A mask plate is placed on a side of the photoresist 18 away from the base substrate 1, the photoresist 18 is exposed and developed using the mask plate as the mask, and then, the remaining photoresist 18 is used as the mask to sequentially etch the protective material layer 13, the metal layer 12, and the first conductive layer 11. That is, the protective material layer 13 is first etched to form a protective layer 131, then, the metal layer 12 and the first conductive layer 11 are etched, where the metal layer 12 is etched to form a connection pin 121, and the first conductive layer 11 is etched to form a conductive pin 111. A set etching amount of the protective material layer 13 is greater than a set etching amount of the metal layer 12, such that after sequentially patterning the protective material layer 13 and the metal layer 12, an orthographic projection of the protective layer 131 on the base substrate 1 is located within an orthographic projection of a surface of the connection pin 121 away from the base substrate 1 on the base substrate 1.

Since the thickness of the metal layer 12 is relatively thick, when the metal layer 12 is being etched, an etching time is relatively long and it is easy to form a circular truncated cone or a truncated pyramid structure with a relatively small upper portion and a relatively large lower portion. For example, the metal layer 12 is etched to form a circular-truncated-cone-shaped connection pin 121, where a diameter of a surface of the connection pin 121 away from the base substrate 1 is R1, a diameter of a surface of the connection pin 121 close to the base substrate 1 is R2, and R1 is less than R2. If the protective material layer 13 still maintains the same set etching amount as the metal layer 12, for example, the protective material layer 13 may be etched to form a circular plate with a diameter of R2, the diameter of the protective layer 131 is greater than the diameter R1 of the surface of the connection pin 121 away from the base substrate 1, resulting in that an edge of the protective layer 131 protrudes from an edge of the connection pin 121, and when the second insulation layer 14 is formed in the subsequent deposition, the second insulation layer 14 is prone to breaking, such that the insulation protection cannot be applied to the connection pin 121.

It should be noted that the etching amount refers to an etching amount in a direction parallel to a surface of the base substrate 1 towards the metal layer 12.

Thus, when the protective material layer 13 is being etched, it is necessary to ensure that there is a certain over-etching amount of the protective material layer 13, and that is, the set etching amount of the protective material layer 13 is greater than the set etching amount of the metal layer 12; the orthographic projection of the protective layer 131 on the base substrate 1 is located within the orthographic projection of the surface of the connection pin 121 away from the base substrate 1 on the base substrate 1, i.e., the orthographic projection of the protective layer 131 on the base substrate 1 may completely overlap with the orthographic projection of the surface of the connection pin 121 away from the base substrate 1 on the base substrate 1, or the orthographic projection of the protective layer 131 on the base substrate 1 may also be located within the orthographic projection of the surface of the connection pin 121 away from the base substrate 1 on the base substrate 1, which means that the orthographic projection of the protective layer 131 on the base substrate 1 is less than the orthographic projection of the surface of the connection pin 121 away from the base substrate 1 on the base substrate 1.

Thus, it may prevent the second insulation layer 14 from breaking during the subsequent formation of the second insulation layer 14, such that the second insulation layer 14 may provide the insulation protection for the connection pin 121.

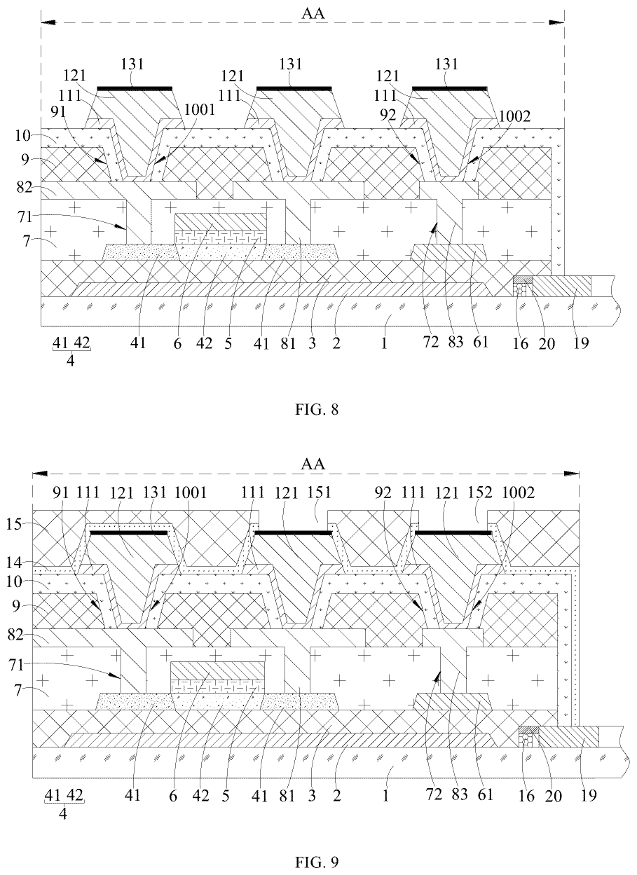

As shown in FIG. 8, the photoresist 18 is removed. As shown in FIG. 9, a second insulation layer 14 is formed on a side of the protective layer 131 away from the base substrate, and a second planarization layer 15 is formed on a side of the second insulation layer 14 away from the base substrate, a seventh via hole 151 and an eighth via hole 152 are formed by patterning the second planarization layer 15 and the second insulation layer 14, the seventh via hole 151 may be communicated to the source 81, and the eighth via hole 152 may be communicated to the ground wire 83.

After the preparation of switch units and the like is completed, the substrate motherboard 1a may be cut to form a plurality of base substrates 1, and then the side lead process may be performed.

In step S30, a part of the flexible film layer 16 is bent to the second surface 102, such that the first part 1611 is opposite to the first surface 101, the second part 1612 is opposite to the side surface 103, and the third part 1613 is opposite to the second surface 102.

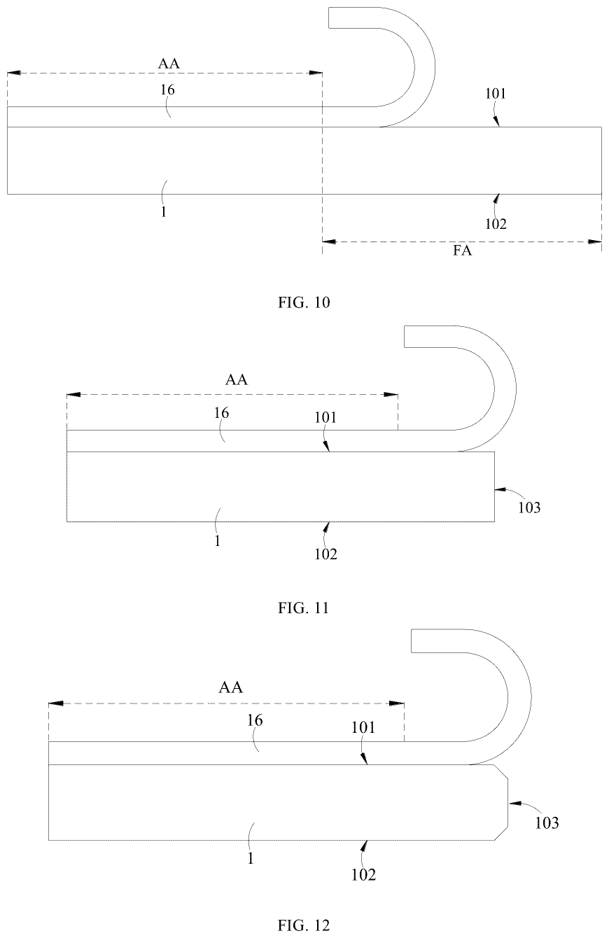

In the present exemplary embodiment, as shown in FIG. 10, the flexible film layer 16 and the isolation layer 20 are bent towards a side away from the second surface 102, such that a part of the flexible film layer 16 is separated from the base substrate 1. Then, as shown in FIG. 11, the exposed part of the base substrate 1 may be removed by cutting, such that an end of the flexible film layer 16 protrudes from the base substrate 1, and even if the flexible film layer 16 is flattened, orthographic projections of the second part 1612 and third part 1613 on the first plane does not overlap with an orthographic projection of the base substrate 1 on the first plane, and the first plane is a plane parallel to the base substrate 1. Finally, as shown in FIG. 12, the edge polishing is performed on the side surface 103 of the base substrate 1, such that a chamfer is formed at an edge connected between the side surface 103 of the base substrate 1 and the first surface 101, and a chamfer is formed at an edge connected between the side surface 103 of the base substrate 1 and the second surface 102. The above chamfer may be a bevel chamfer or a round chamfer. The arrangement of the chamfers enables the connection between the first surface 101 and the side surface 103, as well as the connection between the second surface 102 and the side surface 103 to be relatively smooth, and the subsequently formed conductive layer 17 bends from the first surface 101 to the side surface 103, and from the side surface 103 to the second surface 102, which is also relatively smooth, so as to prevent the conductive layer 17 from forming a small bending corner that is easy to break.

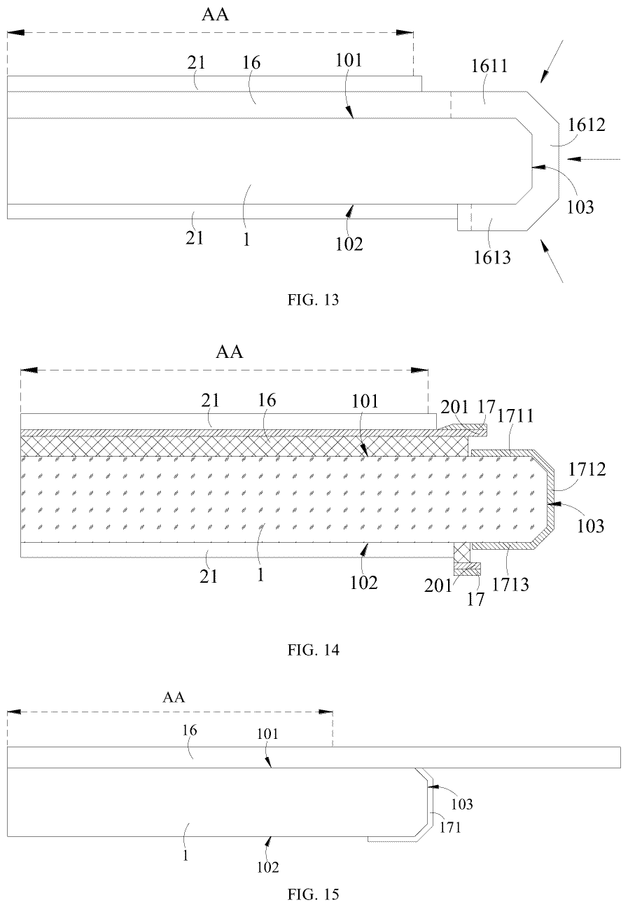

In the present exemplary embodiment, as shown in FIG. 13, the flexible film layer 16 and the end of the isolation layer 20 away from the display area AA are bent to the second surface 102, and the first part 1611 of the first opening portion 161 is opposite to the first surface 101, the second part 1612 of the first opening portion 161 is opposite to the side surface 103, and the third part 1613 of the first opening portion 161 is opposite to the second surface 102.

A set tensile force may be applied to the flexible film layer 16 and the isolation layer 20, that is, a tensile force parallel to the base substrate 1 may be applied to an end of the flexible film layer 16 bent to the second surface 102, such that the bent flexible film layer 16 is fully fitted with the base substrate 1, which avoid a gap formed between the flexible film layer 16 and the base substrate 1. In the case where there is a gap between the flexible film layer 16 and the base substrate 1, when the conductive layer 17 is subsequently formed, the conductive material not only deposits on the base substrate 1 that is not covered by the flexible film layer 16, but also forms on the base substrate 1 that is covered by the flexible film layer 16 through the gap, thereby affecting the precision of the subsequently formed conductive layer 17. Moreover, in the case where a distance between the adjacent first openings 161 is relatively small, the two conductive strips 171 formed may be connected together, resulting in a short circuit of the two conductive strips 171. The flexible film layer 16 is completely fitted with the base substrate 1, which may avoid the occurrence of the aforementioned defects.

In step S40, a conductive layer 17 is formed on a side of the flexible film layer 16 away from the base substrate 1 by using the flexible film layer 16 as a mask, where the conductive layer 17 is formed in at least a part of the first opening portion 161 to form a conductive strip 171.

In the present example embodiment, referring to FIG. 13, the arrow in the drawing shows a direction of sputtering, the flexible film layer 16 is used as the mask, i.e., the flexible film layer 16 serves as a shielding layer; two shielding plates 21 are provided in the display area AA, where one shielding plate 21 is provided on the second surface of the base substrate, and the other shielding plate 21 is provided on the side of the protective layer 131 away from the base substrate to avoid the conductive material from forming in the display area AA. A sputtering device is provided on the side of the flexible film layer 16 away from the base substrate 1, mainly on the side of the flexible film layer 16, which is provided with the first opening portion 161, away from the base substrate 1. There may be provided with a plurality of sputtering devices, and the plurality of sputtering devices form a semi-encirclement to enclose the end of the base substrate 1 that needs to form the conductive strip 171. The plurality of sputtering devices sputter the conductive material from a plurality of directions towards the first opening portion 161 of the flexible film layer 16, the conductive material forms the conductive layer 17, and the conductive layer formed within the first opening portion 161 is the conductive strip 171.

The conductive layer 17 may have a three-layer structure, with the first layer being titanium, the second layer being copper, and the third layer being titanium; and the conductive layer 17 may be formed by sputtering in three stages in a single sputtering process.

As shown in FIG. 14, the conductive strip 171 may include a first conductive part 1711, a second conductive part 1712, and a third conductive part 1713 that are sequentially connected. The first conductive part 1711 is formed in the first part 1611 of the first opening portion 161 and is located on the first surface 101; an area of a part of the first conductive part 1711 away from the second conductive part 1712 is relatively great and may be used as a connecting pad. The second conductive portion 1712 is formed within the second portion 1612 of the first opening portion 161 and is located on the side surface 103; the third conductive part 1713 is formed within the third part 1613 of the first opening portion 161 and is located on the second surface 102. An area of a part of the third conductive part 1713 away from the second conductive part 1712 is relatively great and may also be used as a connecting pad.

As shown in FIG. 14, due to the arrangement of the isolation layer 20, the isolation layer 20 is patterned to form a protrusion portion 201 protruding from the flexible film layer 16. When the conductive layer 17 and the conductive strip 171 are formed by sputtering, due to the obstruction of the protrusion portion 201, the conductive layer 17 formed on the side of the isolation layer 20 away from the base substrate 17 and the conductive strip 171 formed in the first opening portion 161 break, and when the flexible film layer 16 is subsequently peeled off, the flexible film layer 16 does not take the conductive strip 171 away, thereby ensuring the stability of the conductive strip 171.

In step S50, the flexible film layer 16 and the conductive layer 17 that are disposed around the conductive strip 171 are at least removed.

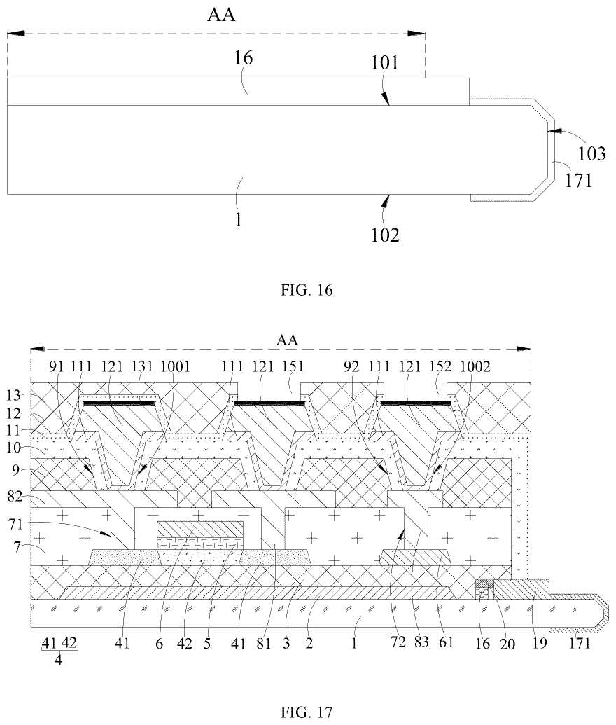

In the present exemplary embodiment, referring to FIG. 15, the flexible film layer 16 is peeled off from the second surface 102, the end surface, and a part of the first surface 101, such that at least a part of the flexible film layer 16 formed with the first opening portion 161 is peeled off from the base substrate 1; then, as shown in FIG. 16, the peeled flexible film layer 16 and conductive layer 17 are cut off. Thus, the flexible film layer 16 and the conductive layer 17 that are around the conductive strip 171 are removed; and the conductive strip 171 is still attached to the first surface 101, the end surface, and the second surface 102 of the base substrate 1.

Of course, in some other exemplary embodiments of the present disclosure, in the case where the flexible film layer 16 and the conductive layer 17 are not provided in the display area AA, the flexible film layer 16 and the conductive layer 17 may also be completely peeled off and removed, leaving only the conductive strip 171.

In this way, the preparation of the driving backplane is completed, and the conductive strip 171 is prepared using the above manner without the need for alignment, thereby simplifying the process and reducing costs. Moreover, the formed conductive strip 171 has high precision and accuracy, and the the etching foreign matter is not produced.

It should be noted that although the various steps of the method for preparing the driving backplane in the present disclosure are described in a specific order in the drawings, this does not require or imply that the steps must be performed in this specific order, or that all of the steps shown must be performed in order to achieve the desired result. Additionally or alternatively, certain steps may be omitted, multiple steps may be combined into one step for execution, and/or one step may be decomposed into multiple steps for execution, etc., all of which should be considered as part of the present disclosure.

Based on the same inventive concept, embodiments of the present disclosure provide a driving backplane, as shown in FIG. 17. The driving backplane is prepared by any of the preparation methods described above.

Specifically, the driving backplane may include a base substrate 1, a light-shielding layer 2 and a flexible film layer 16 located on a side of the base substrate 1, an isolation layer 20 is provided on a side of the flexible film layer 16 away from the base substrate 1, a first opening portion 161 is provided on the flexible film layer 16, a second opening portion 202 is provided on the isolation layer 2, the second opening portion 202 is opposite to the first opening portion 161, and a connection portion 19 is provided within the second opening portion 202 and the first opening portion 161. A conductive strip 171 is provided at an end portion of the base substrate 1 provided with the connection portion 19, and the conductive strip 171 is connected to the connection portion 19 in one-to-one correspondence. Of course, the isolation layer 20 may also be omitted.

The conductive strip 171 includes a first conductive part 1711, a second conductive part 1712, and a third conductive part 1713 that are sequentially connected. The first conductive part 1711 is provided on the first surface 101, the second conductive part 1712 is provided on the side surface 103, and the third conductive part 1713 is provided on the second surface 102. The first conductive part 1711 is connected to the connection portion 19.

A buffer layer 3 is provided on the side of the light-shielding layer 2 away from the base substrate 1 and the side of the isolation layer away from the base substrate 1. Without the isolation layer 20, the buffer layer 3 is provided on the side of the light-shielding layer 2 away from the base substrate 1 and the side of the flexible film layer 16 away from the base substrate 1.

A plurality of switch units provided in an array and a plurality of connection wires are provided on the side of the buffer layer 3 away from base substrate 1. The switch unit may include a capacitor and at least two thin film transistors, the thin film transistor may include an active layer 4, a gate 6, a source 81, and a drain; specifically, an active layer 4 and a connection line 61 are provided on the side of the buffer layer 3 away from the base substrate 1, the active layer 4 may include a channel portion 42 and a conductor portion 41 provided at both ends of the channel portion 42, a gate insulation layer 5 is provided on the side of the active layer 4 away from the base substrate 1, a gate 6 is provided on a side of the gate insulation layer 5, and an interlayer dielectric layer 7 is provided on a side of the gate 6 away from the base substrate 1, a first via hole 71 and a second via hole 72 are defined on the interlayer dielectric layer 7, the first via hole 71 is communicated to the conductor portion 41, and the second via hole 72 is communicated to the connection line 61; a ground wire 83, a source 81, and a drain 82 are provided on a side of the interlayer dielectric layer 7 away from the base substrate 1, and the source 81 and the drain 82 are respectively connected to two conductor portions 41 through two first via holes 71, and the ground wire 83 is connected to the connection line 61 through the second via hole 72. The ground wire 83 is provided as a double-layer structure, which may reduce resistance, and in the case that one of the wires is under the open-circuit condition, the other wire may transmit the signal without affecting the display.

It should be noted that the thin film transistor described in this specification is a top-gate thin film transistor. In other exemplary embodiments of the present disclosure, the thin film transistor may also be a bottom-gate thin film transistor or a double-gate thin film transistor, which is not repeated herein.

The connection wires may include gate wires, data wires, power wires, etc.; the connection wire is connected between the switch unit and the connection portion 19, and an electrical signal is transmitted through the conductive strip 171, the connection portion 19, and the connection wire.

A first planarization layer 9 is provided on a side of the switch unit away from the base substrate 1, and a plurality of third via holes 91 and fourth via holes 92 are provided on the first planarization layer 9; a first insulation layer 10 is provided on a side of the first planarization layer 9 away from the base substrate 1, and a plurality of fifth via holes 1001 and sixth via holes 1002 are provided on the first insulation layer 10.

A conductive pin 111 is provided on a side of the first insulation layer 10 away from the base substrate 1. Two conductive pins 111 are connected to the source 81 and the drain 82 through the third via hole 91 and the fifth via hole 1001, respectively, the other conductive pin 111 is connected to the ground wire 83 through the fourth via hole 92 and the sixth via hole 1002. The conductive pin 111 may be a nickel molybdenum alloy.

A connection pin 121 is provided on a side of the conductive pin 1111 away from the base substrate 1, and a material of the connection pin 121 may be copper.

A protective layer 131 is provided on a side of the connection pin 121 away from the base substrate 1, and a material of the protective layer 131 may be oxide, such as IGZO (Indium Gallium Zinc Oxide), ITZO (Indium Tin Zinc Oxide), etc.

A second insulation layer 14 is provided on a side of the protective layer 131 away from the base substrate, and a second planarization layer 15 is provided on a side of the second insulation layer 14 away from the base substrate. The second planarization layer 15 and the second insulation layer 14 form an insulation layer group, a seventh via hole 151 and an eighth via hole 152 are defined on the insulation layer group. The seventh via hole 151 may be communicated to the source 81, and the eighth via hole 152 may be communicated to the ground wire 83.

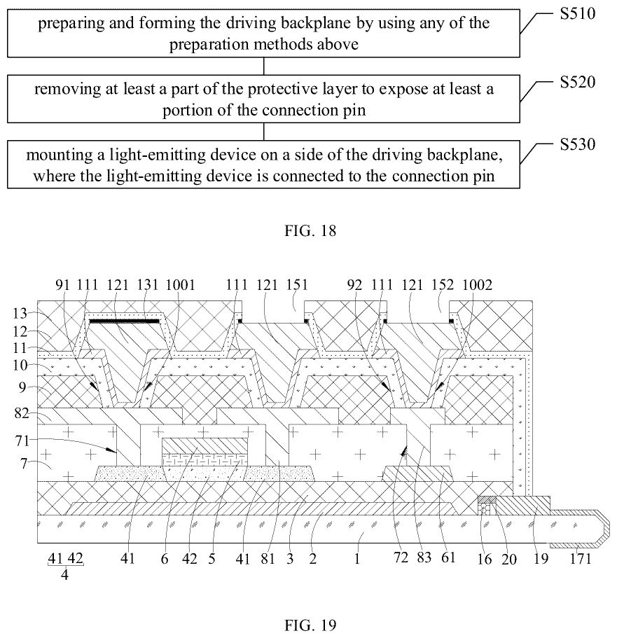

Based on the same inventive concept, the present exemplary embodiments provide a method for preparing a display device, as shown in FIG. 18. The preparation method may include the following steps:
step S510, preparing and forming the driving backplane by using any of the preparation methods described above.
step S520, removing at least a part of the protective layer 131 to expose at least a portion of the connection pin 121.
step S530, mounting a light-emitting device 22 on a side of the driving backplane, where the light-emitting device 22 is connected to the connection pin 121.

The preparation processes of the driving backplane are described in detail above, which is not repeated herein.

In the present exemplary embodiment, as shown in FIG. 19, the protective layer 131 may be corroded by sulfuric acid with low concentration, so as to remove the protective layer 131 and expose the connection pin 121; moreover, the sulfuric acid with low concentration does not damage the connection pin 121.

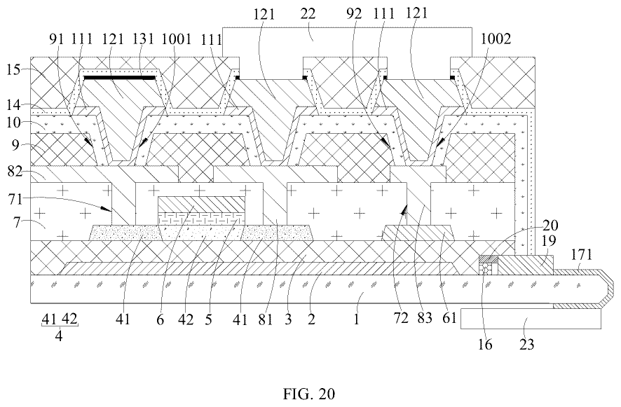

As shown in FIG. 20, through a steel screen printing flux, the light-emitting device 22 is pasted onto a side of the driving backplane with a certain amount of pressure applied, and that is, by “mass transfer”, the light-emitting device 22 is pasted onto the side of the driving backplane; The light-emitting device 22 is connected to the connection pin 121. Specifically, the light-emitting device 22 is provided with an anode and a cathode, the anode of the light-emitting device 22 may be connected to the connection pin 121 that is connected to the source, and the cathode of the light-emitting device 22 may be connected to the connection pin 121 that is connected to the ground wire 83.

Based on the same inventive concept, embodiments of the present disclosure provide a display device, as shown in FIG. 20. The display device is prepared by using the above method for preparing the display device described above.

The display device may include a driving backplane, and a light-emitting device 22 provided on a side of the driving backplane. The light-emitting device 22 may be a micro light-emitting diode, which may be a Micro Light-emitting Diode, with a chip size reduced to less than 50 μm; and the light-emitting device 22 may also be a Mini Light-emitting Diode, which is an LED device with a chip size between 50 to 200 μm.

A circuit board 23 is provided on a side of the driving backplane away from the light-emitting device 22, and the circuit board 23 is provided with a connecting pad, a controller, and various elements. The controller and various components are electrically connected to the connecting pad, the connecting pad is connected to a third conductive part 1713 of the conductive strip 171, and their connections may be bonded by using anisotropic conductive adhesive.

The specific type of the display device is not particularly limited, and any type of display device commonly used in the art may be possible, specifically, for example, mobile devices such as mobile phones, wearable devices such as watches, VR devices. Those skilled in the art may make selection correspondingly according to the specific uses of the display device, which is not be elaborated here.

It should be noted that, it further includes other necessary components and constituents. By taking a display as example, specifically, it may further include a housing, a power cord and the like. Those skilled in the art may make corresponding supplements according to the specific use requirements of the display device, which is not be elaborated here.

Other embodiments of the present disclosure will readily occur to those skilled in the art upon consideration of the description and practice of the present disclosure disclosed here. The present application is intended to cover any variations, uses, or adaptations of the present disclosure that follow the general principles of the present disclosure and include common knowledge or conventional technical means in the field not disclosed by the present disclosure. The description and embodiments are to be regarded as exemplary only, and the true scope and spirit of the present disclosure are indicated by the appended claims.

What is claimed is:

1. A method for preparing a driving backplane, comprising:
providing a base substrate, wherein the base substrate is provided with a first surface and a second surface opposite to each other, a side surface is connected between the first surface and the second surface;
forming a flexible film layer on the first surface, and patterning the flexible film layer to form a first opening portion, wherein the first opening portion comprises a first part, a second part and a third part sequentially connected with each other;
bending a part of the flexible film layer to the second surface, such that the first part is opposite to the first surface, the second part is opposite to the side surface, and the third part is opposite to the second surface;
forming a conductive layer on a side of the flexible film layer away from the base substrate by using the flexible film layer as a mask, wherein the conductive layer is formed in at least a part of the first opening portion to form a conductive strip; and
at least removing the flexible film layer and the conductive layer that are disposed around the conductive strip.

2. The method for preparing the driving backplane according to claim 1, wherein before patterning the flexible film layer, the method further comprises:
forming an isolation layer on the side of the flexible film layer away from the base substrate; and
patterning the isolation layer while patterning the flexible film layer, such that the isolation layer forms a second opening portion, wherein a rate for patterning the isolation layer is less than a rate for patterning the flexible film layer, such that the isolation layer forms a protrusion portion protruding from the flexible film layer at the second opening portion.

3. The method for preparing the driving backplane according to claim 2, wherein a material of the isolation layer is an inorganic material, and a material of the flexible film layer is an organic material.

4. The method for preparing the driving backplane according to claim 1, wherein after patterning the flexible film layer, the method further comprises:
removing a part of the base substrate such that orthographic projections of the second part and the third part on a first plane does not overlap with an orthographic projection of the base substrate on the first plane, wherein the first plane is parallel to the base substrate.

5. The method for preparing the driving backplane according to claim 4, wherein before removing the part of the base substrate, the method further comprises:
bending the flexible film layer towards a side away from the second surface, such that a part of the flexible film layer is separated from the base substrate.

6. The method for preparing the driving backplane according to claim 4, wherein after removing the part of the base substrate, the method further comprises:
forming chamfers by processing a first edge connected between the side surface and the first surface and a second edge connected between the side surface and the second surface.

7. The method for preparing the driving backplane according to claim 6, wherein at least removing the flexible film layer and the conductive layer that are disposed around the conductive strip comprises:
peeling off the flexible film layer from the second surface, an end surface, and at least a part of the first surface; and
at least cutting off the flexible film layer and the conductive layer that are disposed around the conductive strip.

8. The method for preparing the driving backplane according to claim 1, wherein after bending the part of the flexible film layer to the second surface, the method further comprises:
applying a set tensile force to an end portion of the flexible film layer bent to the second surface, such that the flexible film layer is fitted with the base substrate.

9. The method for preparing the driving backplane according to claim 1, wherein after patterning the flexible film layer to form the first opening portion, the method further comprises:
forming a plurality of switch units provided in an array and a plurality of connection wires on a side of the base substrate, wherein the connection wire is connected between the switch unit and the conductive strip;
forming a metal layer on a side of the switch unit away from the base substrate, wherein the metal layer is connected to the switch unit;
forming a protective material layer on a side of the metal layer away from the base substrate;
sequentially patterning the protective material layer and the metal layer, wherein the protective material layer forms a protective layer and the metal layer forms a connection pin; and
forming an insulation layer group on a side of the protective layer away from the base substrate, and patterning the insulation layer group to form a via hole, wherein the via hole is communicated with the protective layer.

10. The method for preparing the driving backplane according to claim 9, wherein a material of the protective material layer is an oxide.

11. The method for preparing the driving backplane according to claim 9, wherein a set etching amount of the protective material layer is greater than a set etching amount of the metal layer, such that after sequentially patterning the protective material layer and the metal layer, an orthographic projection of the protective layer on the base substrate is located within an orthographic projection of a surface of the connection pin away from the base substrate on the base substrate.

12. The method for preparing the driving backplane according to claim 9, wherein before forming the metal layer on the side of the switch unit away from the base substrate, the method further comprises:
forming a first conductive layer on a side of the switch unit away from the base substrate, wherein the metal layer is formed on a side of the first conductive layer away from the base substrate; and
patterning the first conductive layer, while patterning the metal layer, to form a conductive pin.

13. A driving backplane, wherein the driving backplane is prepared according to following steps:
providing a base substrate, wherein the base substrate is provided with a first surface and a second surface opposite to each other, a side surface is connected between the first surface and the second surface;
forming a flexible film layer on the first surface, and patterning the flexible film layer to form a first opening portion, wherein the first opening portion comprises a first part, a second part and a third part sequentially connected with each other;
bending a part of the flexible film layer to the second surface, such that the first part is opposite to the first surface, the second part is opposite to the side surface, and the third part is opposite to the second surface;
forming a conductive layer on a side of the flexible film layer away from the base substrate by using the flexible film layer as a mask, wherein the conductive layer is formed in at least a part of the first opening portion to form a conductive strip; and
at least removing the flexible film layer and the conductive layer that are disposed around the conductive strip.

14. The driving backplane according to claim 13, comprising:
a base substrate, provided with a first surface and a second surface opposite to each other, wherein a side surface is connected between the first surface and the second surface;
a flexible film layer, provided on the first surface;
a buffer layer, located on a side of the flexible film layer away from the base substrate; and
a conductive strip, provided on at least one end portion of the base substrate, wherein the conductive strip comprises a first conductive part, a second conductive part, and a third conductive part sequentially connected, the first conductive part is provided on the first surface, the second conductive part is provided on the side surface, and the third conductive part is provided on the second surface.

15. The driving backplane according to claim 14, further comprising:
an isolation layer, provided between the flexible film layer and the buffer layer.

16. The driving backplane according to claim 14, further comprising:
a plurality of switch units provided in an array and a plurality of connection wires, wherein the plurality of switch units and the plurality of connection wires are provided on a side of the buffer layer away from the base substrate, and the connection wire is connected between the switch unit and the conductive strip;
a connection pin, provided on a side of the switch unit away from the base substrate, wherein the connection pin is connected to the switch unit;
a protective layer, provided on a side of the connection pin away from the base substrate; and
an insulation layer group, provided on a side of the protective layer away from the base substrate, wherein the insulation layer group is defined with a via hole, and the via hole is communicated to the protective layer.

17. A method for preparing a display device, comprising:
preparing and forming the driving backplane by using the method for preparing the driving backplane according to claim 1;
removing at least a part of the protective layer to expose at least a part of the connection pin; and
mounting a light-emitting device on a side of the driving backplane, wherein the light-emitting device is connected to the connection pin.

18. A display device prepared by the method for preparing the display device according to claim 17.

19. The display device according to claim 18, wherein the light-emitting device is a micro light-emitting diode.

20. The display device according to claim 18, wherein the light-emitting device is a mini light-emitting diode, and the mini light-emitting diode is an LED device with a chip size between 50 to 200 μm.
